(19) United States
(12) Patent Application Publication
(10) Pub. No.: US 2026/0155789 A1
(43) Pub. Date: Jun. 4, 2026

(54) AMPLIFIER EQUALIZER MULTI-TONE PEAK ADAPTATION

(71) Applicant: MACOM Technology Solutions Holdings, Inc., Lowell, MA (US)

(72) Inventors: Anil Kumar, Kitchener (CA); Atul Krishna Gupta, Mission Viejo, CA (US); Rajiv Shukla, Burlington (CA); Ryan Suresh Latchman, Irvine, CA (US)

(21) Appl. No.: 19/407,870

(22) Filed: Dec. 3, 2025

Related U.S. Application Data
(60) Provisional application No. 63/727,551, filed on Dec. 3, 2024.

(51) Int. Cl. H03F 1/26; H03F 3/45

(52) U.S. Cl. CPC H03F 1/26; H03F 3/45278; H03F 3/45475; H03F 2200/435

(57) ABSTRACT

Amplifiers with multi-tone peak detection for equalizer adaptation are described herein. An example amplifier circuit includes an amplifier, a multi-tone peak detector coupled to an output of the amplifier, a first control loop, and a second control loop. The multi-tone peak detector is configured to generate a first peak output signal and a second peak output signal based on the output of the amplifier. The first control loop is configured to generate a gain control signal for the amplifier based on the first peak output signal, and the second control loop is configured to generate an equalization control signal for the amplifier based on the first peak output signal and the second peak output signal.

### CROSS-REFERENCE TO RELATED APPLICATIONS

This applications claims the benefit of and priority to U.S. Provisional Patent Application No. 63/727,551, filed Dec. 3, 2024, the entire contents of which is hereby incorporated herein by reference.

### BACKGROUND

A range of different amplifiers are known and relied upon for data communications. Differential amplifiers, as one example, are commonly used for high-speed data communications. Differential amplifiers are designed to amplify the difference between an input signal pair and to reject noise or interference that is present on (i.e., common to) the input signal pair. As another example, distributed amplifiers rely in part on transmission line theory to achieve a relatively larger gain-bandwidth product than that achieved by other types of amplifier circuits. These and other types of amplifiers and amplifier stages are known, and each type of amplifier can have a different amplifier circuit configuration and be relied upon for a different purpose. Multiple amplifier stages of different types can be cascaded together depending on design needs and the amplification application.

### SUMMARY

Certain aspects of the concepts and embodiments described herein are summarized below. The aspects are representative and not exhaustively listed. In alternate embodiments, certain features and elements can be added, omitted, and interchanged with each other. Additionally, variations, extensions, and modifications to the example embodiments can be achieved by those skilled in the art without departing from the concepts, so as to encompass equivalent and related structures.

An example amplifier circuit includes an amplifier, a multi-tone peak detector coupled to an output of the amplifier, a first control loop, and a second control loop. The multi-tone peak detector is configured to generate a first peak output signal and a second peak output signal based on the output of the amplifier. The first control loop is configured to generate a gain control signal for the amplifier based on the first peak output signal, and the second control loop configured to generate an equalization control signal for the amplifier based on the first peak output signal and the second peak output signal. The gain of the amplifier can be adjusted based on the gain control signal, and the frequency-dependent operating response of the amplifier can be adjusted based on the equalization control signal.

In other aspects, the amplifier circuit can also include a reference voltage generator configured to generate a reference voltage, and the first control loop can generate the gain control signal based on a comparison of the first peak output signal with the reference voltage. The second control loop can generate the equalization control signal based on a comparison of the first peak output signal with the second peak output signal. In some implementations, the second control loop includes a controller configured to compare the first peak output signal with the second peak output signal and to generate a difference signal for generation of the equalization control signal. The amplifier circuit can also include a controller to operate a data communications link for external monitoring of the first control loop and the second control loop.

In other aspects, the multi-tone peak detector includes a first differential transistor pair and current mirror for high frequency detection and generation of the first peak output signal, and a second differential transistor pair and current mirror for low frequency detection and generation of the second peak output signal.

Another example amplifier circuit includes an amplifier, a peak detector coupled to an output of the amplifier, and a control loop. The peak detector is configured to generate a first peak output signal and a second peak output signal based on the output of the amplifier. The control loop is configured to generate a gain control signal for the amplifier based on the first peak output signal and to generate an equalization control signal for the amplifier based on the first peak output signal and the second peak output signal.

Another example amplifier circuit includes an amplifier, a driver coupled to an output of the amplifier, a peak detector coupled to an output of the driver, a reference voltage generator, and a controller. The peak detector is configured to generate a first peak output signal and a second peak output signal based on the output of the amplifier. The reference voltage generator is configured to generate a reference voltage. The controller is configured to generate a gain control signal based on a comparison of the first peak output signal with the reference voltage. The controller is also configured to generate an equalization control signal based on a comparison of the first peak output signal with the second peak output signal.

### BRIEF DESCRIPTION OF THE DRAWINGS

Aspects of the present disclosure can be better understood with reference to the following drawings. It is noted that the elements in the drawings are not necessarily drawn to scale, with emphasis instead being placed upon illustrating the principles of the examples. The same reference numerals may designate the same or corresponding elements among two or more figures of the drawings in some, but not necessarily in all, cases.

FIG. 1 illustrates an example multi-stage amplifier according to various examples described herein.

FIG. 2 illustrates an example amplifier circuit with a control and correction loop according to various examples described herein.

FIG. 3 illustrates another example amplifier circuit with control and correction loops according to various examples described herein.

FIG. 4 illustrates an example circuit topology of the multi-tone peak detector used in the amplifier circuit shown in FIG. 3 according to various examples described herein.

### DETAILED DESCRIPTION

Receivers, transmitters, and transceivers for emerging data communication applications rely upon amplifier circuits to transfer data signals at higher speeds. The amplifiers are often designed for broadband operation, variable gain control, and other operating characteristics. Multiple amplifier stages in a multi-stage amplifier, including a combination of differential, distributed, variable gain, driver, and other types of amplifiers can be cascaded or connected in series depending on the design needs for the amplifier application. Amplifier design often includes the evaluation of a number of operating characteristics of the amplifier, such as amplifier biasing, gain, high-frequency peaking, operating bandwidth, input and output characteristics, small signal parameters, stability, and other operating characteristics.

An amplifier can rely upon single-tone peak detection for gain control. The gain control loop can be relied upon to ensure a fixed output amplitude despite changing input amplitudes. To extend the operational benefits of such amplifiers, new amplifiers incorporating multi-tone peak detection for both gain control and equalizer adaptation are described herein. An example amplifier circuit includes an amplifier, a multi-tone peak detector coupled to an output of the amplifier, and one or more control loops. The amplifier can include a first control loop and a second control loop in one implementation. The multi-tone peak detector can be configured to generate a first peak output signal and a second peak output signal based on the output of the amplifier. The first control loop can be configured to generate a gain control signal for the amplifier based on the first peak output signal, and the second control loop can be configured to generate an equalization control signal for the amplifier based on the first peak output signal and the second peak output signal. These and other aspects of the embodiments are described below.

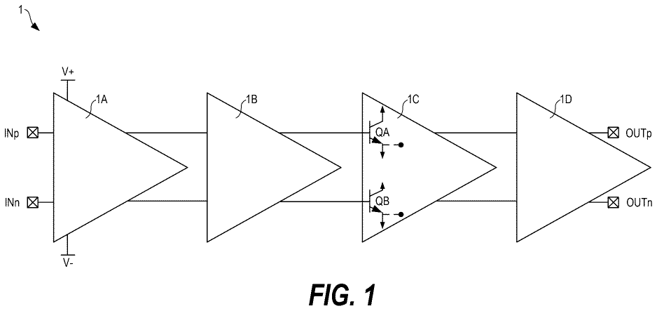

FIG. 1 illustrates an example amplifier circuit 1 according to various examples described herein. The amplifier circuit 1 is a multi-stage amplifier and can be embodied in various ways, such as using discrete components, as an integrated circuit device formed on a substrate, or as a combination of discrete components and integrated devices. The amplifier circuit 1 is depicted as a representative example. The amplifier circuit 1 is not exhaustively illustrated in FIG. 1, and the amplifier circuit 1 can include additional components that are not shown in some cases. In other cases, the amplifier circuit 1 can omit one or more of the amplifier stages shown.

The amplifier circuit 1 includes a number of cascaded amplifier circuits or stages, including amplifier stages 1A-1D, among possibly others. In the cascaded configuration shown, the outputs of the amplifier stage 1A are provided as inputs to the amplifier stage 1B. The outputs of the amplifier stage 1B are provided as inputs to the amplifier stage 1C, and so on. Multi-stage amplifiers can be relied upon for increased overall gain, to tailor input or output impedances, and to achieve other objectives. Each of the amplifier stages 1A-1D is supplied with power by an upper rail voltage or potential V+ and a lower rail voltage or potential V−.

Each of the amplifier stages 1A-1D can include one or more transistor amplifiers, biasing circuitry, coupling circuitry, control circuitry, and related circuit components. One or more of the amplifier stages 1A-1D can also include and rely upon control loops that control the operation of the amplifier stages 1A-1D. The control loops can generate gain, equalization, and related types of control signals, as feedback to direct and control the operation of one or more of the amplifier stages 1A-1D. The transistors in the amplifier stages 1A-1D can be arranged or configured in different ways (e.g., differential pair, Darlington pair, common collector or drain, common emitter or source, or common base or gate, etc.) depending on the design, objectives, and application for the multi-stage amplifier 1. The amplifier stage 1C is shown to include two common collector transistors QA and QB, as an example for handling a differential signal, and other arrangements of transistors can be relied upon among the amplifier stages 1A-1D.

Each of the amplifier stages 1A-1D can be designed, tailored, and optimized independently. For some purposes or applications of the multi-stage amplifier 1, one or more of the amplifier stages 1A-1D can include multi-tone peak detection circuitry and one or more control loops for gain and equalizer adaptation. These and other aspects of the embodiments are described below. The multi-tone peak detection and control loop concepts described herein are not limited to use with multi-stage amplifiers, amplifiers at any particular location in a multi-stage amplifier, or any particular type of amplifier. The concepts can be extended to and used with a range of different types of amplifiers, including those designed for wired and wireless communications, radio frequency (RF) communications, optical communications, and for other applications in data communications, without limitation.

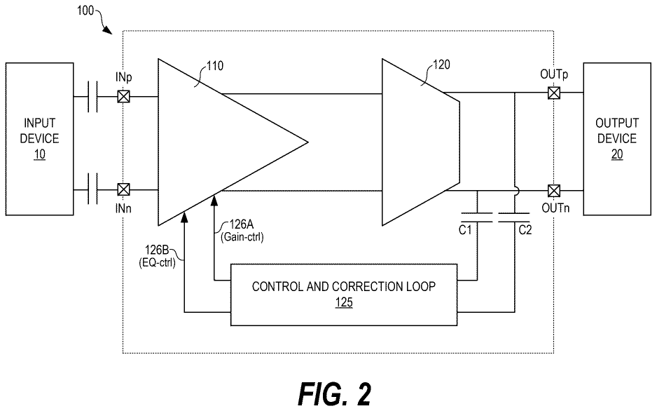

FIG. 2 illustrates an example amplifier circuit 100 according to various examples described herein. The amplifier circuit 100 can be embodied in various ways, such as using discrete components, as an integrated circuit device formed on a substrate, or as a combination of discrete components and integrated devices. The amplifier circuit 100 is depicted as a representative example. The amplifier circuit 100 is not exhaustively illustrated in FIG. 2, and the amplifier circuit 100 can include additional components that are not shown in some cases. The amplifier circuit 100 can be implemented as a standalone amplifier, as an amplifier stage in a multi-stage amplifier, or in other amplifier circuit configurations. The amplifier circuit 100 can be used for wired and wireless communications, RF communications, optical communications, and for other applications in data communications, without limitation. As one example, the amplifier circuit 100 can be relied upon to drive an optical modulator in a pluggable module of an active optical cable assembly, but the amplifier circuit 100 and the concepts described herein are not limited to any particular field of technology or communications.

The amplifier circuit 100 includes an input, an output, an amplifier 110, a driver 120, and a control and correction loop 125 (also “control loop 125”). In the example shown in FIG. 2, the input to the amplifier circuit 100 is a differential input signal, which is provided to the differential inputs INp and INn from the input device 10. A differential output from the amplifier 110 is coupled to a differential input of the driver 120. A differential output from the driver 120 is provided to differential outputs OUTp and OUTn, which are coupled to an output device 20 in the example shown.

The input device 10 provides a differential input signal to the differential inputs INp and INn as an input to the amplifier circuit 100. The differential input signal can be a signal encoded using a data encoding or modulation technique, such as pulse amplitude modulation (PAM), on off keying (OOK), amplitude shift keying (ASK), frequency shift keying (FSK), phase shift keying (PSK), quadrature phase shift keying (QPSK), quadrature amplitude modulation (QAM), or another modulated technique. A PAM input signal, a 4-level PAM (PAM-4) input signal, or another order of PAM-modulated input signal can be provided to the amplifier circuit 100 in one example. The output device 20 receives an output from the amplifier circuit 100 at the differential outputs OUTp and OUTn. The amplifier circuit 100 can also be connected in other ways, to other input devices, other output devices, and to other amplifier stages in other implementations. The amplifier circuit 100 can be part of the amplifier circuit 1 shown in FIG. 1 in some cases.

The amplifier 110 can be embodied as a variable gain amplifier (VGA) with gain and equalization (e.g., bandwidth) control. As one example, the amplifier 110 can be implemented using a transistor circuit having a topology for variable gain signal amplification and for bandwidth control, including one or more differential transistor pairs, one or more current sources, coupling capacitors, and other components. The amplifier 110 is designed to have adjustable gain based on a gain control signal, as described herein. The amplifier 110 is also designed to exhibit a frequency-dependent operating response based on an equalization control signal, as described herein. The amplifier 110 can be implemented using bipolar junction transistors, field effect transistors (FETs), and other types of transistors.

The driver 120 can be embodied as a transistor circuit having a topology suitable for use as a buffer or driver, with a differential output. As one example, the driver 120 can be designed to output the same (or substantially the same) differential output signal from the amplifier 110, at a higher current capacity (e.g., with a reduced output impedance).

As described in further detail below, the control loop 125 is configured to generate a gain control signal 126A (also “Gain-ctrl signal 126A”) and provide the Gain-ctrl signal 126A to the amplifier 110. The control loop 125 is also configured to generate an equalization control signal 126B (also “EQ-ctrl signal 126B”) and provide the EQ-ctrl signal 126B to the amplifier 110. The gain of the amplifier 110 can be controlled or adjusted based on the Gain-ctrl signal 126A, and the frequency-dependent operating response (e.g., frequency-dependent gain) of the amplifier 110 can be controlled or adjusted based on the EQ-ctrl signal 126B. Adjustments to the frequency-dependent operating response of the amplifier 110 can be particularly important for some applications, such as where the input or output signals of the amplifier 110 are expected to experience variances in frequency-dependent gain, linearity, noise, extinction ratio, and other operating criteria.

The control loop 125 can be implemented using discrete, integrated, or a combination of discrete and integrated components in various implementations. The control loop 125 can also be implemented in analog, digital, or a mixture of analog and digital circuitry, with or without memory. Among other components, the control loop 125 can include one or more peak detectors, comparators, analog-to-digital converters (ADCs), digital-to-analog converters (DAC), controllers, and other components.

The control loop 125 is configured to generate one or more peak-to-peak signals and one or more reference voltages. The peak-to-peak signals can be representative of the peak-to-peak output voltage swing of the amplifier 110 at one or more frequencies or tones. In one implementation, a peak detector in the control look 125 can generate a first peak-to-peak signal representative of the output voltage swing of the amplifier 110 at a first frequency or tone. The peak detector in the control loop 125 can also generate a second peak-to-peak signal representative of the output voltage swing of the amplifier 110 at a second frequency or tone, where the first frequency is different than the second frequency.

The control loop 125 is configured to compare the peak-to-peak signals with the reference voltages and generate one or more gain difference signals based on the comparisons. The control loop 125 can compare the first peak-to-peak signal, the second peak-to-peak signal, or both the first and second peak-to-peak signals with a reference voltage to generate one or more gain difference signals. In one example, the control loop 125 can generate the Gain-ctrl signal 126A based on a comparison between a first peak-to-peak signal and a reference voltage. The control loop 125 can provide the Gain-ctrl signal 126A to the amplifier 110, and the gain of the amplifier 110 can be adjusted based on the Gain-ctrl signal 126A.

The control loop 125 is also configured to compare the peak-to-peak signals with each other, to generate one or more equalization difference signals. In one example, the control loop 125 can compare a first peak-to-peak signal related to a first frequency or tone with a second peak-to-peak signal related to a second frequency or tone, to generate an equalization difference signal. The control loop 125 can also generate the EQ-ctrl signal 126B based on the equalization difference signal. The control loop 125 provides the EQ-ctrl signal 126B to the amplifier 110, and a frequency-dependent operating response of the amplifier 100 is adjusted based on the EQ-ctrl signal 126B. The control loop 125 can also interface with a host device by a local bus, enabling external monitoring, diagnostics, and adaptive control of the gain and equalization settings of the amplifier 100.

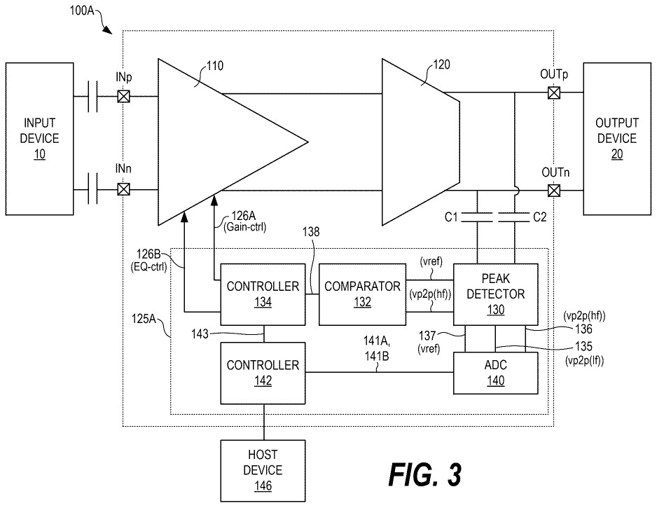

FIG. 3 illustrates another example amplifier circuit 100A with control and correction loops according to various examples described herein. The amplifier circuit 100A can be embodied in various ways, such as using discrete components, as an integrated circuit device formed on a substrate, or as a combination of discrete components and integrated devices. The amplifier circuit 100A is depicted as a representative example. The amplifier circuit 100A is not exhaustively illustrated in FIG. 3, and the amplifier circuit 100A can include additional components that are not shown in some cases. The amplifier circuit 100A can be implemented as a standalone amplifier, as an amplifier stage in a multi-stage amplifier, or in other amplifier circuit configurations. The amplifier circuit 100A can be used for wired and wireless communications, RF communications, optical communications, and for other applications in data communications, without limitation.

The amplifier circuit 100A shown in FIG. 3 includes an input, an output, the amplifier 110, the driver 120, and the control loop 125A. The control loop 125A shown in FIG. 3 is an example implementation of the control loop 125 of the amplifier circuit 100 shown in FIG. 2. The control loop 125A includes a first control loop for gain control and a second control loop for equalizer control. The first control loop includes a peak detector 130, a comparator 132, and a controller 134. The second control loop includes the peak detector 130, an ADC 140, and a controller 142. The peak detector 130 may be considered a component separate from both the first and second control loops in some cases.

The differential output of the driver 120 is coupled through capacitors C1 and C2 to inputs of the control loop 125 and, more particularly, to the peak detector 130. The taps from the differential outputs of the driver 120 can be made as close to the driver 120 as possible, to reduce stub length.

The peak detector 130 can be embodied as a single-tap, multi-tone peak output detector. In the example shown, the peak detector 130 is configured to generate a first peak output signal 135 (also “vp2p(lf) signal 135”) and a second peak output signal 136 (also “vp2p(hf) signal 136”) based on the output of the amplifier 110 and, more particularly, the output of the driver 120. The peak detector 130 can also generate a reference voltage signal 137 (also “vref signal 137”). Alternatively, the vref signal 137 can be generated by a voltage reference generator or source other than (i.e., separate from) the peak detector 130.

The peak detector 130 is configured to generate the vp2p(lf) signal 135 as an analog voltage representative of the peak-to-peak output voltage swing of the amplifier 110 at one or more lower frequencies or tones. The peak detector 130 is configured to generate the vp2p(hf) signal 136 as an analog voltage representative of the peak-to-peak output voltage swing of the amplifier 110 at one or more higher frequencies or tones. The peak detector 130 is not limited to generating two peak output signals. The peak detector 130 can generate and output any number of peak-to-peak output voltage swing signals for any number of different frequencies, frequency bands, or tones.

As an example, the peak detector 130 can be designed to generate the vp2p(lf) signal 135 and the vp2p(hf) signal 136 at frequencies related to the baud rate of data communications through the amplifier circuit 100. The peak detector 130 can be designed to generate the vp2p(lf) signal 135 at a frequency between about 10 KHz to the baud rate divided by 5 (e.g., baud rate/5). The peak detector 130 can also be designed to generate the vp2p(hf) signal 136 at a frequency between about the baud rate divided by 5 and the baud rate.

As another example, the peak detector 130 can be designed to generate the vp2p(hf) signal 136 at a higher frequency selected based on the Nyquist bandwidth of the amplifier circuit 100. The frequency corresponding to the vp2p(hf) signal 136 can be one-half, one-quarter, one-eighth, or some other fraction of the Nyquist bandwidth of the amplifier circuit 100. The peak detector 130 can also be designed to generate the vp2p(lf) signal 135 at a lower frequency than the vp2p(hf) signal 136, such as at a frequency related to the baud rate or a ratio of the baud rate of data communications through the amplifier circuit 100.

In the first control loop, the vref signal 137 and the vp2p(lf) signal 135 are provided as inputs to the comparator 132, which can be embodied as a difference amplifier or comparator. The comparator 132 is configured to generate a reference difference signal 138 based on the difference in electric potential between the vref signal 137 and the vp2p(lf) signal 135, over time. The reference difference signal 138 from the comparator 132 is provided as an input to the controller 134. The reference difference signal 138 can be an analog value representative of the difference in potential between the vref signal 137 and the vp2p(lf) signal 135, a digital (e.g., true/false or count) signal representative of whether or not the vp2p(lf) signal 135 is greater than or less than the vref signal 137, or another type of analog or digital output that varies over time. When providing a digital output, the comparator 132 can be considered a type of ADC converter.

The controller 134 can be embodied as mixed analog and digital control logic, as an integrated mixed-signal microcontroller with memory, or as a related type of control logic or processing circuitry. The controller 142 can also be embodied as mixed analog and digital control logic, as an integrated mixed-signal microcontroller with memory, or related control logic or processing circuitry. In some cases, the controllers 134 and 142 can be embodied as a single integrated or combined controller.

Either or both of the controllers 134 and 142 can be embodied as a programmable device with analog and digital input and output interfaces and processing capabilities. The controllers 134 and 142 can also include integrated ADCs, DACs, counters, and related circuitry with inputs and outputs in some cases. The controllers 134 and 142 can also be programmed to operate one or more timers, pulse width modulation (PWM) interfaces, communication interfaces (e.g., SPI, I²C, UART, CAN, RS232, RS422, USB, etc. interfaces), and other types of custom logic and custom interfaces in some cases.

The controller 134 is configured to generate the Gain-ctrl signal 126A based on the reference difference signal 138 provided from the comparator 132. The controller 134 can generate the Gain-ctrl signal 126A to be proportional, linearly proportional, inversely proportional, inversely linearly proportional, or to have another functional relationship with respect to the reference difference signal 138. As one example, when a potential of the difference output signal from the comparator 132 increases, the controller 134 can be configured to increase a potential of the Gain-ctrl signal 126A. When the potential of the difference output signal from the comparator 132 decreases, the controller 134 can be configured to decrease a potential of the Gain-ctrl signal 126A. However, in other cases, the controller 134 can be configured to generate the Gain-ctrl signal 126A inversely with respect to the reference difference signal 138, either with or without a scalar factor. The controller 134 is also configured to generate the EQ-ctrl signal 126B. The controller 134 can generate the EQ-ctrl signal 126B based on the reference difference signal 138 and the output of the controller 142.

In the second control loop, the ADC 140 is configured to convert the vp2p(lf) signal 135 and the vp2p(hf) signal 136 from analog to digital format. More particularly, the ADC 140 is configured to convert the vp2p(lf) signal 135 and the vp2p(hf) signal 136 from analog to digital format based on a comparison of each with the vref signal 137. Thus, the ADC 140 is configured to generate digital signals that are proportional to or representative of the vp2p(lf) signal 135 and the vp2p(hf) signal 136, with reference to the vref signal 137, and provide the digital signals to the controller 142 for further processing.

The ADC 140 can output a first digital signal 141A representative of the difference between the vp2p(lf) signal 135 and the vref signal 137 over time. The ADC 140 can also output a second digital signal 141B representative of the difference between the vp2p(hf) signal 136 and the vref signal 137 over time. As a more particular example, the first digital signal 141A can be representative of how much the vp2p(lf) signal 135 is greater than or less than the vref signal 137 over time. The second digital signal 141B can be representative of how much the vp2p(hf) signal 136 is greater than or less than the vref signal 137 over time. The first digital signal 141A and the second digital signal 141B are provided as outputs from the ADC 140 and as inputs to the controller 142.

The controller 142 is configured to compare the digital signals 141A and 141B and provide an equalization difference signal 143 to the controller 134. That is, the controller 142 is configured to generate the equalization difference signal 143 as a signal representative of the difference between the digital signal 141A and the digital signal 141B, over time. The difference signal 143 can be a digital signal in at least one implementation and is representative of the difference between the first digital signal 141A and the second digital signal 141B.

The controller 142 can also be configured to operate a local interface, such as an I²C serial communications bus or related communications link. In the example shown in FIG. 3, the controller 142 is coupled to a host device 146 by the local interface. The host device 146 can receive data from and send data to the controller 142 over the local interface. The local interface can provide access to data stored in the controller 142 for monitoring, evaluation, and further processing by the host device 146. Through the local interface, the host device 146 can monitor the operations of the amplifier circuit 100, monitor the first control loop for gain control, monitor the second control loop for equalizer control, and control the gain, equalization, and other operational aspects of the amplifier circuit 100. Thus, the local interface provides a means for the host device 146 to perform diagnostics and equalization control adaptation on the amplifier circuit 100. As one example, through the local interface, the host device 146 can control or adjust one or both of the Gain-ctrl signal 126A and the EQ-ctrl signal 126B.

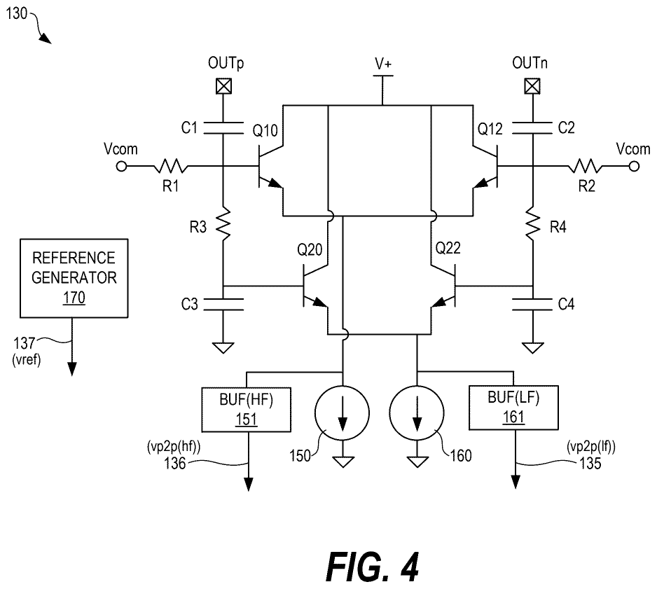

FIG. 4 illustrates an example circuit topology of the peak detector 130 in the amplifier circuit 100 shown in FIG. 3. The peak detector 130 includes capacitors C1, C2, C3, C4, resistors R1, R2, R3, and R4, a first differential pair of transistors Q10 and Q12, a second differential pair of transistors Q20 and Q22, a first current source 150, a first buffer network 151, a second current source 160, and a second buffer network 161 coupled together in the arrangement shown. The emitter terminals of the first differential pair of transistors Q10 and Q12 are coupled together and coupled to the first current source 150. The OUTp and OUTn signals from the driver 120 are coupled through the capacitors C1 and C2, respectively, to the base terminals of the transistors Q10 and Q12. A Vcom bias voltage is applied through the resistors R1 and R2 to the base terminals of the transistors Q10 and Q12.

The emitter terminals of the second differential pair of transistors Q20 and Q22 are coupled together and coupled to the second current source 160. Resistors R3 and R4 are coupled between the base terminals of the transistors Q10 and Q12, respectively, and the base terminals of the transistors Q20 and Q22. The capacitors C3 and C4 are coupled between the base terminals of the transistors Q20 and Q22, respectively, and signal ground.

The first current source 150 can be implemented as any suitable type of current source or related biasing circuitry for the differential transistors Q10 and Q12. Examples of the first current source 150 include transistor-based current mirrors, current regulators, resistors, and combinations thereof, and the first current source 150 is not limited to any particular type of current source. The first current source 150 can also be implemented as a variable current source in some cases. The second current source 160 can be implemented as any suitable type of current source or related biasing circuitry for the differential transistors Q20 and Q22. Examples of the second current source 160 include transistor-based current mirrors, current regulators, resistors, and combinations thereof, and the second current source 160 is not limited to any particular type of current source. The second current source 160 can also be implemented as a variable current source in some cases.

The resistors R1-R4 and the capacitors C3 and C4 form filters or filter networks at the base or input terminals of the differential transistors Q10 and Q12 and the differential transistors Q20 and Q22. The resistance and capacitance values of the resistors R1-R4 and the capacitors C3 and C4 can be selected to control the frequency responsiveness of the vp2p(lf) signal 135 and the vp2p(hf) signal 136.

The peak detector 130 operates as a multi-tone peak detector. Based on the circuit topology of the peak detector 130, the peak detector 130 is configured to generate the vp2p(lf) signal 135 as an analog voltage representative of the peak-to-peak output voltage swing of the amplifier 110 at a lower frequency or tone. The peak detector 130 is also configured to generate the vp2p(hf) signal 136 as an analog voltage representative of the peak-to-peak output voltage swing of the amplifier 110 at a higher frequency or tone. As an example, the peak detector 130 can be designed to generate the vp2p(hf) signal 136 at one or more relatively higher frequencies based on the Nyquist bandwidth of the amplifier circuit 100. The peak detector 130 can also be designed to generate the vp2p(lf) signal 135 at one or more relatively lower frequencies based on data communications at a particular data rate. The peak detector 130 can also be extended to generate more than two peak-to-peak output voltage swing signals in other cases.

The peak detector 130 also includes a reference voltage generator 170. The reference voltage generator 170 is configured to generate the vref signal 137 as a precisely controlled, and in some cases temperature compensated, reference potential. The reference voltage generator 170 can be embodied as a type of bandgap reference circuit, by a reverse bias diode and operational amplifier buffer, by a precision resistor divider and operational amplifier buffer, by a dedicated voltage reference integrated circuit, or using another suitable reference voltage circuit. The reference voltage generator 170 can also be separate from the peak detector 130 in other implementations.

The amplifier circuit embodiments described herein, which are capable of making gain and frequency-dependent operating response adjustments over time, can compensate for a range of effects that impact bit error rates. The amplifier circuits include a multi-tone peak detector, an automatic gain correction (AGC) loop, and an equalization correction loop, which operate on high-and low-frequency peak detection signals and provide digital monitoring available via a local interface. The peak detector outputs are digitized and accessible for diagnostics, allowing for continuous monitoring and adaptive control without disrupting the data communications signal link through the amplifier circuit. The dual-loop approach ensures robust performance by compensating for impairments and facilitating real-time diagnostics and equalization adjustments.

The transistors described herein, including the transistors can be implemented as a range of different types of transistors formed in a range of different semiconductor materials. The transistors can be formed as bipolar junction transistors, FETs, variants thereof, and other types of transistors, and the concepts can be applied to a range of transistor types. Among other types of FET transistors, the transistors described herein can be formed as high-electron mobility transistors (HEMTs), pseudomorphic high-electron mobility transistors (pHEMTs), metamorphic high-electron mobility transistors (mHEMTs), and other types of transistors. The FETs can include metal oxide or insulator semiconductor (MOSFET or MISFET) transistors and metal-semiconductor field-effect transistor (MESFETs). The transistors can include one or more field plates, such as source-connected field plates, gate-connected field plates, or both source-connected and gate-connected field plates. The transistors can be implemented in silicon germanium (SiGe), gallium arsenide (GaAs), gallium nitride (GaN), GaN materials, and other semiconductor materials on or over a range of different substrates. As non-limiting examples, the transistors can be structured as enhancement or depletion mode FET transistors, such as a depletion mode GaAs pHEMT transistors, as GaN HEMT transistors, as GaN materials HEMT transistors, or as related power transistors.

The transistors and other active devices described herein can be formed using group III-V semiconductor materials and semiconductor manufacturing processes. The group III elemental materials include scandium (Sc), aluminum (Al), gallium (Ga), and indium (In), and the group V elemental materials include nitrogen (N), phosphorus (P), arsenic (As), and antimony (Sb)). Thus, in some examples, the concepts can be applied to group III-V active semiconductor devices, such as the III-Nitrides (aluminum (Al)-, gallium (Ga)-, indium (In)-, and alloys (AlGaIn)-based Nitrides), GaAs, InP, InGaP, AlGaAs, etc. devices. However, the concepts may be applied to transistors and other active devices formed from other semiconductor materials.

The concepts described herein can be embodied by GaN-on-Si transistors and devices, GaN-on-SiC transistors and devices, as well as other types of semiconductor materials. As used herein, the phrase “gallium nitride material(s)” or “GaN material(s)” refers to gallium nitride and any of its alloys, such as aluminum gallium nitride (AlₓGa₍₁₋ₓ₎N), indium gallium nitride (In_{y}Ga_{(1-y)}N), aluminum indium gallium nitride (AlₓIn_{y}Ga_{(1-x-y)}N), gallium arsenide phosphide nitride (GaAsₐP_{b}N_{(1-a-b)}), aluminum indium gallium arsenide phosphide nitride (AlₓIn_{y}Ga_{(1-x-y)} AsₐP_{b}N_{(1-a-b)} ), among others. Typically, when present, arsenic and/or phosphorous are at low concentrations (e.g., less than 5 weight percent). The gallium nitride materials can be n-type doped, p-type doped, or unintentionally doped (UID). The term “gallium nitride” or “GaN” refers directly to gallium nitride, exclusive of its alloys (i.e., x=y=a=b=0). The GaN can be n-type doped, p-type doped, or unintentionally doped (UID).

In view of the limitations of the semiconductor manufacturing and processing techniques available in the field, the terms “approximately” and “about” reflect a certain inability (or uncertainty) to precisely control the exact dimensions of certain features described herein. Depending on the level of precision that can be achieved using the commercially available semiconductor processing tools available at the time, the terms “approximately” and “about” may be used to mean within ±20% of a target value for some features, within ±10% of a target value for some features, within ±5% of a target value for some features, and within ±2% of a target value for some features. The terms “approximately” and “about” may include the target value.

The concepts described herein can be combined in one or more embodiments in any suitable manner, and the features discussed in the embodiments are interchangeable in some cases. Example embodiments are described herein, although a person of skill in the art will appreciate that the technical solutions and concepts can be practiced in some cases without all of the specific details of each example. Additionally, substitute or equivalent steps, components, materials, and the like may be employed. It should also be appreciated that some well-known process steps, semiconductor material layers, semiconductor device features, and other features have been omitted to avoid obscuring the concepts.

Although relative terms such as “on,” “below,” “upper,” “lower,” “top,” “bottom,” “right,” and “left” may be used to describe the relative spatial relationships of certain structural features, these terms are used for convenience only, as a direction in the examples. Thus, if a structure is turned upside down, the “upper” component will become a “lower” component. When a structure or feature is described as being “on” (or formed on) another structure or feature, the structure can be positioned directly on (i.e., contacting) the other structure, without any other structures or features intervening between the structure and the other structure. When a structure or feature is described as being “over” (or formed over) another structure or feature, the structure can be positioned over the other structure, with or without other structures or features intervening between them. When two components are described as being “coupled to” each other, the components can be electrically coupled to each other, with or without other components being electrically coupled and intervening between them. When two components are described as being “directly coupled to” each other, the components can be electrically coupled to each other, without other components being electrically coupled between them.

Terms such as “a,” “an,” “the,” and “said” are used to indicate the presence of one or more elements and components. The terms “comprise,” “include,” “have,” “contain,” and their variants are used to be open ended and may include or encompass additional elements, components, etc., in addition to the listed elements, components, etc., unless otherwise specified. The terms “first,” “second,” etc. may be used as differentiating identifiers of individual or respective components among a group thereof, rather than as a descriptor of a number of the components, unless clearly indicated otherwise.

Although embodiments have been described herein in detail, the descriptions are by way of example. The features of the embodiments described herein are representative and, in alternative embodiments, certain features and elements can be added or omitted. Additionally, modifications to aspects of the embodiments described herein can be made by those skilled in the art without departing from the spirit and scope of the present invention defined in the following claims, the scope of which are to be accorded the broadest interpretation so as to encompass modifications and equivalent structures.

Therefore, the following is claimed:

1. An amplifier circuit comprising:
an amplifier;
a multi-tone peak detector coupled to an output of the amplifier, the multi-tone peak detector being configured to generate a first peak output signal and a second peak output signal based on the output of the amplifier;
a first control loop configured to generate a gain control signal for the amplifier based on the first peak output signal; and
a second control loop configured to generate an equalization control signal for the amplifier based on the first peak output signal and the second peak output signal.

2. The amplifier circuit according to claim 1, wherein the multi-tone peak detector comprises:
a first differential transistor pair and current mirror for high frequency detection and generation of the first peak output signal; and
a second differential transistor pair and current mirror for low frequency detection and generation of the second peak output signal.

3. The amplifier circuit according to claim 1, further comprising:
a reference voltage generator configured to generate a reference voltage, wherein the first control loop is configured to generate the gain control signal based on a comparison of the first peak output signal with the reference voltage.

4. The amplifier circuit according to claim 1, wherein the second control loop is configured to generate the equalization control signal based on a comparison of the first peak output signal with the second peak output signal.

5. The amplifier circuit according to claim 1, wherein the second control loop comprises a controller configured to compare the first peak output signal with the second peak output signal and to generate a difference signal for generation of the equalization control signal.

6. The amplifier circuit according to claim 1, wherein the second control loop comprises a controller configured to operate a data communications link for external monitoring of the first control loop and the second control loop.

7. The amplifier circuit according to claim 1, wherein a gain of the amplifier is adjusted based on the gain control signal, and a frequency-dependent operating response of the amplifier is adjusted based on the equalization control signal.

8. The amplifier circuit according to claim 1, wherein the second control loop comprises a controller configured to operate a local interface for external control of at least one of the gain control signal or the equalization control signal and monitoring of at least one of the first control loop or the second control loop.

9. The amplifier circuit according to claim 1, further comprising a driver coupled to the amplifier, wherein the multi-tone peak detector is coupled to an output of the driver.

10. An amplifier circuit comprising:
an amplifier;
a peak detector coupled to an output of the amplifier, the peak detector being configured to generate a first peak output signal and a second peak output signal based on the output of the amplifier; and
a control loop configured to generate a gain control signal for the amplifier based on the first peak output signal and generate an equalization control signal for the amplifier based on the first peak output signal and the second peak output signal.

11. The amplifier circuit according to claim 10, wherein the peak detector comprises:
a first differential transistor pair and current mirror for high frequency detection and generation of the first peak output signal; and
a second differential transistor pair and current mirror for low frequency detection and generation of the second peak output signal.

12. The amplifier circuit according to claim 10, further comprising:
a reference voltage generator configured to generate a reference voltage, wherein the control loop is configured to generate the gain control signal based on a comparison of the first peak output signal with the reference voltage.

13. The amplifier circuit according to claim 10, wherein the control loop is configured to generate the equalization control signal based on a comparison of the first peak output signal with the second peak output signal.

14. The amplifier circuit according to claim 10, wherein the control loop comprises a controller configured to compare the first peak output signal with the second peak output signal and to generate a difference signal for generation of the equalization control signal.

15. The amplifier circuit according to claim 10, wherein a gain of the amplifier is adjusted based on gain control signal, and a frequency-dependent operating response of the amplifier is adjusted based on the equalization control signal.

16. The amplifier circuit according to claim 10, wherein the control loop comprises a controller configured to operate a local interface for external control of at least one of the gain control signal or the equalization control signal.

17. An amplifier circuit comprising:
an amplifier;
a driver coupled to an output of the amplifier;
a peak detector coupled to an output of the driver, the peak detector being configured to generate a first peak output signal and a second peak output signal based on the output of the amplifier;
a reference voltage generator configured to generate a reference voltage; and
a controller configured to:
generate a gain control signal based on a comparison of the first peak output signal with the reference voltage; and
generate an equalization control signal based on a comparison of the first peak output signal with the second peak output signal.

18. The amplifier circuit according to claim 17, wherein the controller is configured to generate the equalization control signal based on a difference between the first peak output signal and the second peak output signal.

19. The amplifier circuit according to claim 17, wherein the peak detector comprises:
a first differential transistor pair and current mirror for high frequency detection and generation of the first peak output signal; and
a second differential transistor pair and current mirror for low frequency detection and generation of the second peak output signal.

20. The amplifier circuit according to claim 17, wherein a gain of the amplifier is adjusted based on gain control signal, and a frequency-dependent operating response of the amplifier is adjusted based on the equalization control signal.
